(19) United States
(12) Patent Application Publication
(10) Pub. No.: US 2009/0128878 A1
(43) Pub. Date: May 21, 2009

(54) Scanner and display device having the same

(75) Inventors: Chang-Keun Jun, Siheung-si (KR); Hyuck-Dong Kwon, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electro-Mechanics Co., Ltd., Suwon (KR)

(21) Appl. No.: 12/149,609

(22) Filed: May 5, 2008

(30) Foreign Application Priority Data
Nov. 20, 2007 (KR) 10-2007-0118285

(51) Int. Cl. G02B 26/10; G02B 26/08; G01R 33/07

(52) U.S. Cl. 359/199.3; 324/207.2; 359/213.1

(57) ABSTRACT

A scanner and a display device. The scanner may include: a mirror positioned on a light path for reflecting light; a mirror holder supporting the mirror; a housing rotatably supporting the mirror holder; a driving unit rotating the mirror holder such that the mirror rotates periodically in an oscillatory manner; a sensing magnet coupled to a rotation center of the mirror holder and rotating in correspondence to a rotation of the mirror holder; and a Hall sensor coupled to the housing adjacent to the sensing magnet for sensing a rotation of the mirror holder. With certain embodiments, the periodical oscillating rotations of the mirror can be detected and used for feedback control, so that the mirror may reflect light with greater stability. Certain embodiments can be used to supplement the driving force of the driving unit, and can prevent noise that may occur during the rotation of the mirror.

### CROSS-REFERENCE TO RELATED APPLICATIONS

This application claims the benefit of Korean Patent Application No. 10-2007-0118285 filed with the Korean Intellectual Property Office on Nov. 20, 2007, the disclosure of which is incorporated herein by reference in its entirety.

### BACKGROUND

1. Technical Field

The present invention relates to a scanner, and to a display device equipped with the scanner.

2. Description of the Related Art

A scanner is a device which reflects light to form an image on a screen, and may be used in a barcode reader or a display device, etc. In particular, there are active development efforts geared towards implementing ultra-small scanners, for application in current portable equipment or cell phones, but due to the small size of the picture, there are limits in expanding the functionality, as well as in popularizing the products.

In a scanner according to the related art, the driving force of a driving unit may periodically rotate a mirror in an oscillating manner, so that light received from a light source may be projected onto a screen by an optical modulator to form an image.

According to the related art, however, when the mirror is oscillated periodically, the position and speed of the mirror may not be controlled with high precision, posing difficulties in forming an even image. Also, there is no structure for supplementing the driving force, so that power may be wasted when the rotating direction of the mirror is changed.

As such, there is a need for a scanner, and a display device having the scanner, which can reflect light and form an even, high-resolution image in a stable manner, and which are equipped with a device for noiselessly supplementing the driving force of the driving unit.

### SUMMARY

An aspect of the invention provides a scanner and a display device having the scanner, which can reflect light in a stable manner, and which are equipped with a device that noiselessly supplements the rotation of the mirror.

Another aspect of the invention provides a scanner that includes: a mirror, which is positioned on a light path, and which reflects light; a mirror holder, which supports the mirror; a housing, which rotatably supports the mirror holder; a driving unit, which rotates the mirror holder such that the mirror rotates periodically in an oscillatory manner; a sensing magnet, which is coupled to a rotation center of the mirror holder, and which rotates in correspondence to a rotation of the mirror holder; and a Hall sensor, which is coupled to the housing adjacent to the sensing magnet, and which senses a rotation of the mirror holder.

The sensing magnet can be shaped as a circular plate, and a center axis of the sensing magnet can be positioned at a rotation center of the mirror holder.

The driving unit may include: a driving coil, which may be coupled to the housing, and of which the polarities may be adjusted; and a driving magnet, which may be coupled to the mirror holder, and which may be inserted through the driving coil according to a change in polarity of the driving coil.

In certain embodiments, the scanner may further include a supplementing unit, which may provide a rotational force that supplements the rotation of the mirror holder, when the rotational direction of the mirror holder is changed.

The supplementing unit may include multiple supplementing magnets, which may be arranged with the driving magnet interposed in-between, to provide magnetic forces to the driving magnet.

The supplementing unit can include an elastic member which may provide an elastic force to the mirror holder.

A support part can be formed in the housing, and the elastic member can include a spring that has one end coupled to the mirror holder and the other end supported by the support part to provide an elastic force according to a rotation of the mirror holder.

A soundproofing member may be included, which can be coupled to the support part and configured to reduce noise due to the contact between the support part and the other end of the spring.

The soundproofing member can include a damper interposed between the support part and the other end of the spring.

The soundproofing member can include a support string, which may be coupled to the support part and to the other end of the spring, to prevent contact between the support part and the other end of the spring.

The support string may include multiple unit support strings, each of which may have either end coupled to the support part and the other end of the spring.

In certain embodiments, a hole may be formed in the other end of the spring, where both ends of the support string may be coupled to the support part, and the support string may be coupled to the other end of the spring through the hole, so that the spring may be able to slide along the support string.

Yet another aspect of the invention provides a display device that includes: a light source; an optical modulator, which modulates and outputs light received from the light source; and a scanner, which scans the light received from the optical modulator onto a screen. Here, the scanner includes: a mirror, which is positioned on a light path, and which reflects light; a mirror holder, which supports the mirror; a housing, which rotatably supports the mirror holder; a driving unit, which rotates the mirror holder such that the mirror rotates periodically in an oscillatory manner; a sensing magnet, which is coupled to a rotation center of the mirror holder, and which rotates in correspondence to a rotation of the mirror holder; and a Hall sensor, which is coupled to the housing adjacent to the sensing magnet, and which senses a rotation of the mirror holder.

The sensing magnet can be shaped as a circular plate, and a center axis of the sensing magnet can be positioned at a rotation center of the mirror holder.

The driving unit may include: a driving coil, which may be coupled to the housing, and of which the polarities may be adjusted; and a driving magnet, which may be coupled to the mirror holder, and which may be inserted through the driving coil according to a change in polarity of the driving coil.

In certain embodiments, the display device may further include a supplementing unit, which may provide a rotational force that supplements the rotation of the mirror holder, when the rotational direction of the mirror holder is changed.

The supplementing unit may include multiple supplementing magnets, which may be arranged with the driving magnet interposed in-between, to provide magnetic forces to the driving magnet.

The supplementing unit can include an elastic member which may provide an elastic force to the mirror holder.

A support part can be formed in the housing, and the elastic member can include a spring that has one end coupled to the mirror holder and the other end supported by the support part to provide an elastic force according to a rotation of the mirror holder.

A soundproofing member may be included, which can be coupled to the support part and configured to reduce noise due to the contact between the support part and the other end of the spring.

The soundproofing member can include a damper interposed between the support part and the other end of the spring.

The soundproofing member can include a support string, which may be coupled to the support part and to the other end of the spring, to prevent contact between the support part and the other end of the spring.

The support string may include multiple unit support strings, each of which may have either end coupled to the support part and the other end of the spring.

In certain embodiments, a hole may be formed in the other end of the spring, where both ends of the support string may be coupled to the support part, and the support string may be coupled to the other end of the spring through the hole, so that the spring may be able to slide along the support string.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view illustrating a scanner based on a first disclosed embodiment of an aspect of the invention.

FIG. 2 is a cross-sectional view across line X-X′ of FIG. 1.

FIG. 3 and FIG. 4 are cross-sectional views illustrating the operation of a scanner based on the first disclosed embodiment of an aspect of the invention.

FIG. 5 is a diagram schematically illustrating a sensing magnet used in a scanner based on the first disclosed embodiment of an aspect of the invention.

FIG. 6 is a graph representing the magnetic flux of a sensing magnet detected by a Hall sensor in a scanner based on the first disclosed embodiment of an aspect of the invention.

FIG. 7 is a graph representing the elastic force in a spring in a scanner based on the first disclosed embodiment of an aspect of the invention.

FIG. 8 is a graph representing changes in rotation angle of the mirror holder, when the elastic force in the spring follows the line “E” in FIG. 7.

FIG. 9 is a graph representing changes in rotation angle of the mirror holder, when the elastic force in the spring follows the line “C” in FIG. 7.

FIG. 10 is a cross-sectional view illustrating the operation of a scanner based on a second disclosed embodiment of an aspect of the invention.

FIG. 11, FIG. 12, and FIG. 13 are diagrams schematically illustrating a spring and a support string as utilized in a scanner based on the second disclosed embodiment of an aspect of the invention.

FIG. 14 is a cross-sectional view illustrating a scanner based on a third disclosed embodiment of an aspect of the invention.

FIG. 15 and FIG. 16 are cross-sectional views illustrating the operation of a scanner based on the third disclosed embodiment of an aspect of the invention.

FIG. 17, FIG. 18, and FIG. 19 are cross-sectional views illustrating a scanner based on a fourth disclosed embodiment of an aspect of the invention.

FIG. 20 is a cross-sectional view illustrating a scanner based on a fifth disclosed embodiment of an aspect of the invention.

FIG. 21 is a cross-sectional view illustrating a display device based on an embodiment of another aspect of the invention.

### DETAILED DESCRIPTION

The scanner and display device according to certain embodiments of the invention will be described below in more detail with reference to the accompanying drawings. Those components that are the same or are in correspondence are rendered the same reference numeral regardless of the figure number, and redundant explanations are omitted.

Also, if a component is described to be coupled to another component, the coupling not only refers to those cases where the components are in direct physical contact, but also encompasses those cases where a different element or elements are interposed between the components mentioned, with the components being in contact with the different element or elements respectively.

Also, feedback refers to an automatic adjusting principle, where an output resulting from an input is fed back to the input to decrease or increase the output. The term “feedback” will hereinafter be used to convey this or a similar meaning.

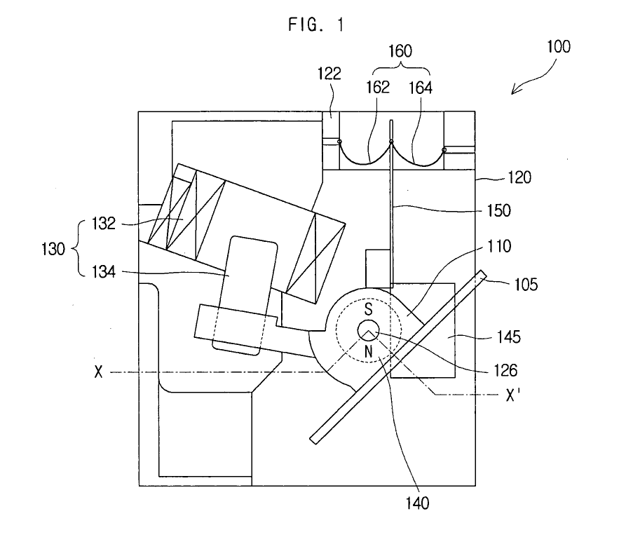

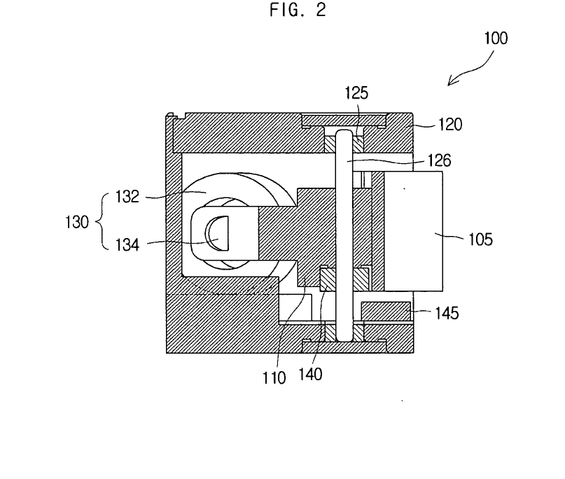

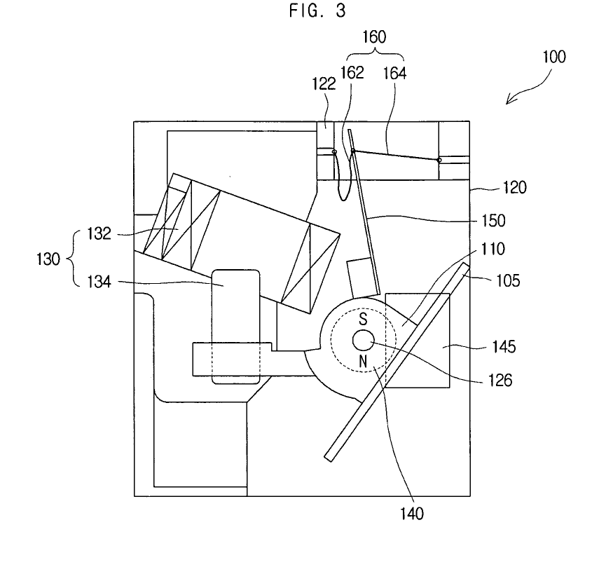

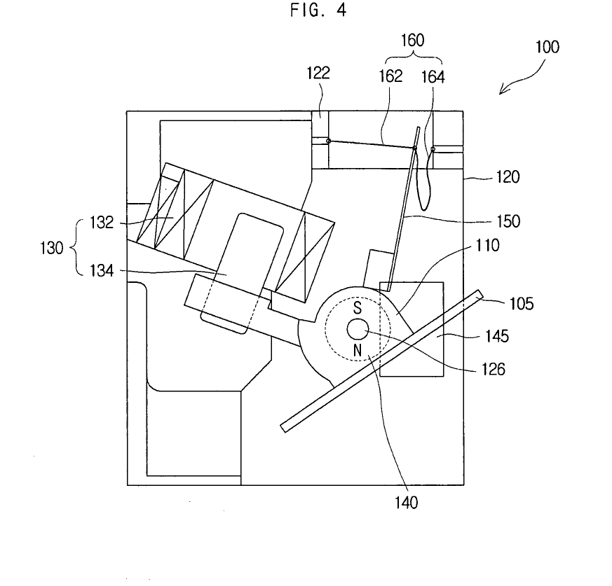

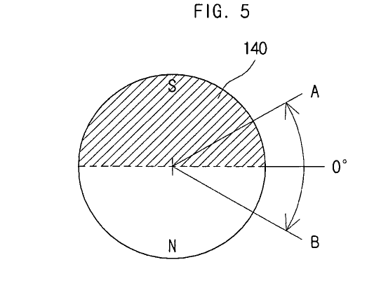

FIG. 1 is a cross-sectional view illustrating a scanner based on a first disclosed embodiment of an aspect of the invention, FIG. 2 is a cross-sectional view across line X-X′ of FIG. 1, and FIGS. 3 and 4 are cross-sectional views illustrating the operation of a scanner based on the first disclosed embodiment of an aspect of the invention.

In FIGS. 1 to 4, there are illustrated a scanner 100, a mirror 105, a mirror holder 110, a housing 120, a support part 122, a bearing 125, a rotation shaft 126, a driving unit 130, a driving coil 132, a driving magnet 134, a sensing magnet 140, a Hall sensor 145, a spring 150, a support string 160, and unit support strings 162, 164.

In this embodiment, a scanner 100 is presented, in which the periodical oscillating rotations of the mirror 105 and mirror holder 110 may be detected by the sensing magnet 140 and Hall sensor 145 and provided as feedback, so that light may be reflected in a more uniform manner. Also, a spring 150 that has one end secured may be used as a supplementing unit, to supplement the rotation of the mirror holder 110 when the rotation direction of the mirror holder 110 is changed. In addition, by using a support string 160 as a soundproofing member, noise can be prevented that may otherwise be caused when the other end of the spring 150 contacts the housing 120.

A mirror 105 may be positioned on a light path to reflect light. That is, after light projected from a light source passes an optical modulator and becomes modulated, the light may be reflected on the mirror 105 to form an image on a screen.

Here, as the mirror 105 undergoes oscillatory rotations at a particular frequency within a limited range of rotation angles, the light modulated by the optical modulator may be projected as an image onto the screen. In one example, the mirror 105 may rotate in an oscillatory manner within the range of 20 to 22 degrees at a frequency of 100 Hz or higher.

A mirror holder 110 may support the mirror 105. That is, the mirror 105 may be secured to one side of the mirror holder 110, and the driving force generated in a driving unit 130 may be transferred to the other side of the mirror holder 110, so that the mirror 105 may undergo oscillating rotations within a limited range of angles, as described above.

In this case, a rotation shaft 126 may be coupled through the rotation center of the mirror holder 110, and the rotation shaft 126 may be rotatably coupled to the housing 120 by way of a bearing 125, so that the mirror 105 and mirror holder 110 may undergo oscillating rotations about the rotation shaft 126.

The housing 120 may support the mirror holder 110 such that the mirror holder 110 is capable of rotating. Since the rotation shaft 126 may be coupled at the rotation center of the mirror holder 110, and the rotation shaft 126 may be rotatably coupled to the housing 120, as described above, the mirror holder 110 may rotate about the same rotation center as that of the rotation shaft 126.

Also, a support part 122 may be formed in the housing 120 that supports the other end of the spring 150, whereby the spring 150 can be made to serve as a supplementing unit and provide an elastic force that supplements the rotational force of the mirror holder 110 when the direction of rotation of the mirror holder 110 is changed. This will be described further in the descriptions for the supplementing unit.

The driving unit 130 may rotate the mirror holder 110, such that the mirror 105 may undergo oscillating rotations periodically. As described above, the mirror 105 may project light within a limited range of angles, in order to form an image on the screen. To this end, the driving unit 130 may oscillate the mirror holder 110 at a particular frequency within a limited range of rotation angles, causing the mirror 105 secured to the mirror holder 110 to also undergo oscillating rotations at the particular frequency within the limited range of rotation angles.

The driving unit 130 can be composed of a driving coil 132 and a driving magnet 134. The driving coil 132 may be coupled to the housing 120, and may have adjustable polarities. The driving magnet 134 may be coupled to the other side of the mirror holder 110, and may be inserted through the driving coil 132 according to changes in polarity of the driving coil 132.

That is, when electricity is supplied to the driving coil 132 in a particular direction, a magnetic field may be generated that results in an attraction between the driving coil 132 and the driving magnet 134, whereby the driving magnet 134 may be inserted through the driving coil 132. Conversely, when electricity is supplied in an opposite direction, the polarity of the driving coil 132 may be changed such that a repulsion is applied between the driving coil 132 and the driving magnet 134, whereby the driving magnet 134 inserted through the driving coil 132 may be removed to the exterior.

A sensing magnet 140, shaped as a circular plate, may be coupled to the mirror holder 110, such that the center axis of the sensing magnet 140 is positioned at the rotation center of the mirror holder 110, so that the sensing magnet 140 may rotate in correspondence with the rotation of the mirror holder 110.

That is, the sensing magnet 140 may be coupled to the perimeter of the rotation shaft 126, which may be coupled at the rotation center of the mirror holder 110, such that the center axis of the sensing magnet 140 may coincide with the rotation center of the mirror holder 110. Thus, when the mirror holder 110 is rotated, the sensing magnet 140 may also be rotated about its center axis.

A Hall sensor 145 may be coupled to the housing 120 adjacent to the sensing magnet 140, and may be configured to detect the rotation of the mirror holder 110. With the sensing magnet 140 coupled to the mirror holder 110 such that it is positioned at the rotation center of the mirror holder 110, and with the Hall sensor 145 coupled to an area of the housing 120 adjacent to the sensing magnet 140 so as to recognize the magnetic field of the sensing magnet 140, the Hall sensor 145 may detect the rotation of the mirror holder 110 to generate a sensing signal corresponding to the rotation. This sensing signal can be inputted to a control part (not shown), which can generate a signal for controlling the driving unit 130.

As the sensing magnet 140 may be coupled at the center of rotation of the mirror holder 110, it is possible to detect the position of the mirror holder 110 not only at either end points at which the direction of rotation is changed, but also at all positions with the range of rotation angles. A sensing signal corresponding to the position may be generated, which may be inputted to the control part (not shown). The control part (not shown) may then output a compensation signal as feedback to the driving unit 130, to control the position or speed of the rotating mirror holder 110, so that the mirror holder 110 may undergo oscillatory rotations in a more stable and more uniform manner.

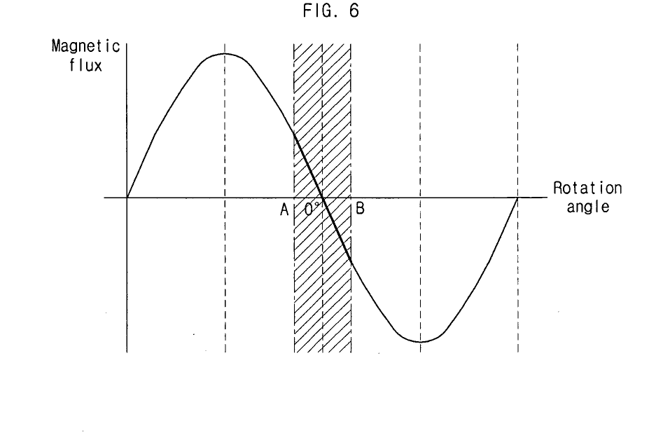

A description will be provided below, with reference to FIGS. 5 and 6, on the feedback control enabled by positioning the sensing magnet 140 at the rotation center of the mirror holder 110.

FIG. 5 is a diagram schematically illustrating a sensing magnet used in a scanner based on the first disclosed embodiment of an aspect of the invention, and FIG. 6 is a graph representing the magnetic flux of a sensing magnet detected by a Hall sensor in a scanner based on the first disclosed embodiment of an aspect of the invention.

As illustrated in FIG. 5, the sensing magnet 140 may be shaped as a circular plate, and may have its center axis positioned at the center of rotation of the mirror holder 110. As such, when the sensing magnet 140 periodically oscillates within the limited range of rotation angles (A, B), the magnetic field detected by the Hall sensor 145 adjacent to the sensing magnet 140 may not be affected by the shape of the sensing magnet 140, making it possible to detect the magnetic field of the sensing magnet 140 with greater precision.

Also, with the sensing magnet 140 coupled to the rotation center of the mirror holder 110, the magnetic field of the sensing magnet 140 detected by the Hall sensor 145 according to the rotation angle of the mirror holder 110 may follow a sinusoidal wave, as illustrated in FIG. 6. In the range of angles (A, B), within which the mirror 105, mirror holder 110, and sensing magnet 140 periodically oscillates, a substantially linear relation can be found.

The magnetic filed of the sensing magnet 140 within this linear section can be detected by the Hall sensor 145, which may generate a sensing signal and transfer the signal to the control part (not shown). The control part (not shown) may generate a corresponding compensation signal, allowing feedback for controlling the driving unit 130, and as a result, the mirror 105 and mirror holder 110 may undergo rotating oscillations in a more stable and uniform manner to reflect light.

A supplementing unit may provide a rotating force that supplements the rotation of the mirror holder 110, when the direction of rotation of the mirror holder 110 is changed during the oscillatory rotations. The supplementing unit can include an elastic member that provides an elastic force to the mirror holder 110. The elastic member can be a spring 150, e.g. a flat spring, that has one end coupled to the mirror holder 110 and the other end supported by the support part 122 of the housing according to the rotation of the mirror holder 110 to provide an elastic force.

With the supplementing unit coupled to the mirror holder 110, the supplementing unit may provide elastic forces to the mirror holder 110 when the mirror holder 110, made to undergo oscillating rotations by the driving unit 130, is changed in its direction of rotation. Thus, the mirror holder 110 can be made to oscillate with greater ease, and consequently, the power consumption required by the scanner 100 can be reduced, whereby the size of the driving unit 130 may be decreased, and a more compact scanner 100 may be implemented.

By using a spring 150 for the supplementing unit that has one end coupled to the mirror holder 110 and the other end unrestrained and supported by the support part 122 of the housing 120 in correspondence with the points at which the rotation of the mirror holder 110 changes direction, the elastic force of the spring 150 may not be applied while the mirror holder 110 is rotating, before the change in rotation direction, to prevent unnecessary waste in power consumed by the driving unit 130. The elastic force of the spring 150 can be applied only at the points where the rotation of the mirror holder 110 changes direction, to supplement the operation of the mirror holder 110.

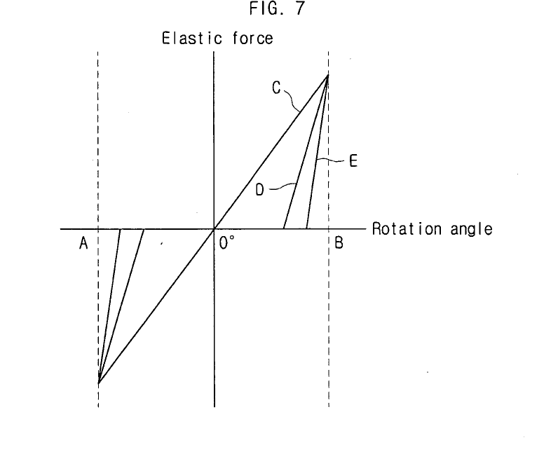

FIG. 7 is a graph representing the elastic force in a spring in a scanner based on the first disclosed embodiment of an aspect of the invention. FIG. 7 illustrates the elastic force of the spring 150 for the case where both ends of the spring 150 are secured (C) and for the cases where only one end of the spring 150 is secured (D, E).

As described above, in cases where only one end of the spring 150 is secured to the mirror holder 110 (D, E), the elastic force of the spring 150 may be applied only near the points where the rotation of the mirror holder 110 changes direction, and may not be applied during the rotation of the mirror holder 110, so that unnecessary waste in power consumption may be avoided.

Also, in cases where only one end of the spring 150 is secured to the mirror holder 110 (D, E), the rotation angle at which the spring 150 is supported by the support part 122 of the housing 120 and thus at which the elastic force is applied may be adjusted. Thus, at the positions where the rotation direction of the mirror holder 110 is changed, the amount of power consumed and the controllability of the change in rotation direction can be balanced. This will be described further in the descriptions for the soundproofing member.

While this embodiment has been described with a spring 150 having one fixed end as an example of the supplementing unit, it is to be appreciated that the invention encompasses other compositions and coupling relationships known to those skilled in the art that are capable of supplementing the driving force of the driving unit 130. Some such examples will be described later with reference to the fourth and fifth disclosed embodiments of the invention.

A soundproofing member may be coupled to the support part 122 to prevent noise that may occur when the other end of the spring 150 contacts the support part 122. The soundproofing member can be a support string 160, which may be coupled to the support part 122 and the other end of the spring 150, to prevent contact between the other end of the spring 150 and the support part 122. The support string 160 can include multiple unit support strings 162, 164, which may each have either end coupled respectively to the support part 122 and the other end of the spring 150.

That is, as illustrated in FIGS. 3 and 4, each unit support string 162, 164 can have one end coupled to the support part 122 of the housing 120 and the other coupled to the other end of the spring 150, to prevent the other end of the spring 150 from touching the support part 122 of the housing 120 near the points where the rotation of the mirror holder 110 changes direction. In this way, noise that may occur due to the contact between the other end of the spring 150 and the support part 122 may be prevented.

In this case, a material which is easily bent but is not deformed lengthwise can be used for the unit support strings 162, 164. Then, by adjusting the lengths of the unit support strings 162, 164, the rotation angles of the mirror holder 110 at which the elastic force is applied can be adjusted, as illustrated in FIG. 7. In this way, unnecessary waste in power consumption may be avoided, while the rotation of the mirror holder 110 may be controlled with greater ease, as the duration in which the rotation direction of the mirror holder 110 is changed may be prolonged.

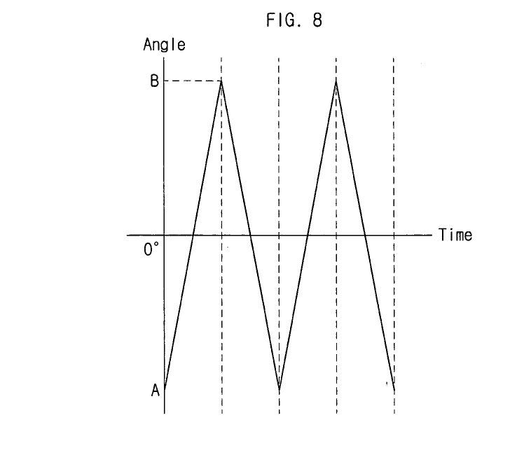

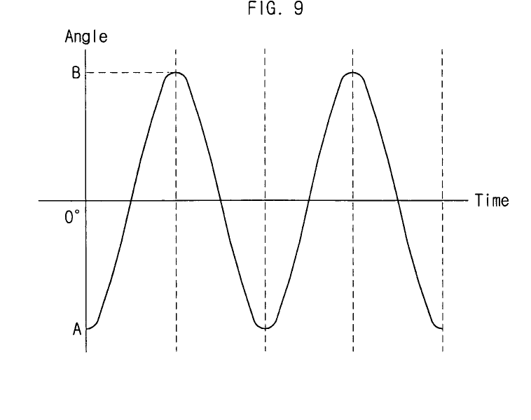

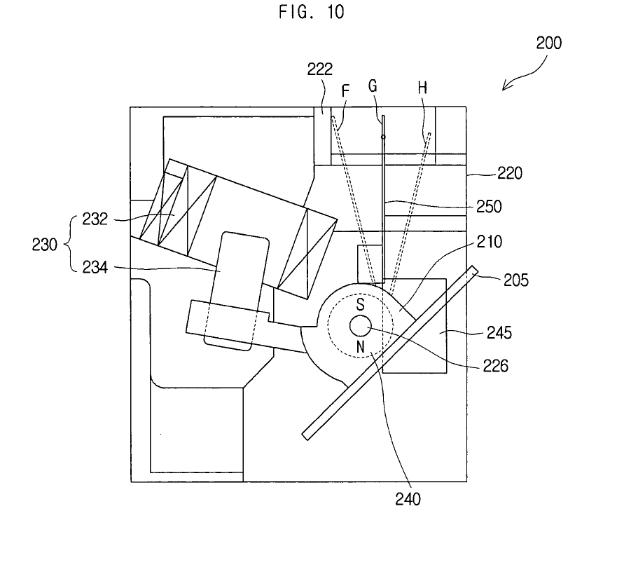

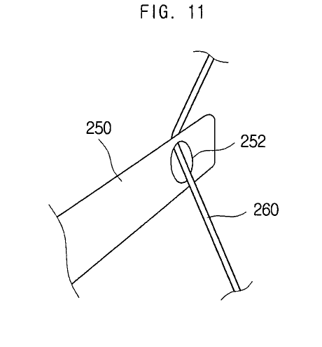

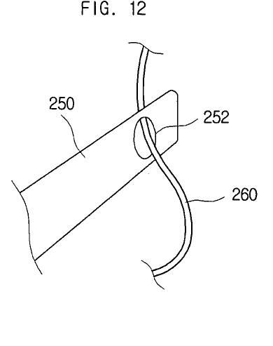

FIG. 8 is a graph representing changes in rotation angle of the mirror holder, when the elastic force in the spring follows the line “E” in FIG. 7, and FIG. 9 is a graph representing changes in rotation angle of the mirror holder, when the elastic force in the spring follows the line “C” in FIG. 7.

As illustrated in FIG. 8, for the cases where only one end of the spring 150 is secured (D, E), if the lengths of the unit support strings 162, 164 are lengthened (E), there may be less waste in power consumption, but more difficulty in controlling the driving when the rotation direction of the mirror holder 110 is changed. Conversely, as illustrated in FIG. 9, in cases where the lengths of the unit support strings 162, 164 are shortened, to correspond to the case where both ends of the spring 150 are secured (C), there may be more waste in power consumption but greater ease in controlling the driving when the rotation direction of the mirror holder 110 is changed.

Therefore, even in cases where only one end of the spring 150 is secured (D, E), the consumption of power and the controllability regarding the direction of rotation of the mirror holder 110 can be balanced, by adjusting the lengths of the unit support strings 162, 164 such that the unit support strings 162, 164 restrain the other end of the spring 150 with margins before the points at which the rotational direction of the mirror holder 110 is changed (D).

While this embodiment has been described with an arrangement of unit support strings 162, 164 as an example of the soundproofing member, it is to be appreciated that the invention encompasses other compositions and coupling relationships known to those skilled in the art that are capable of preventing or reducing noise caused by contact between the other end of the spring 150 and the support part 122. Some such examples will be described later with reference to the second and third disclosed embodiments of the invention.

Next, a description will be provided for a second disclosed embodiment, in which a support string is used as the soundproofing member that may pass through a hole in the other end of the spring and to couple with the housing.

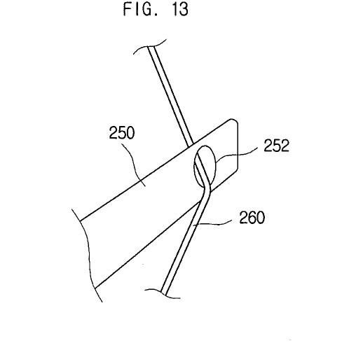

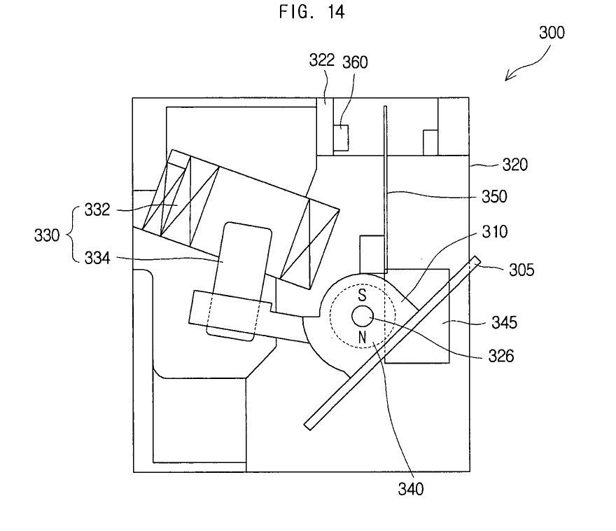

FIG. 10 is a cross-sectional view illustrating the operation of a scanner based on a second disclosed embodiment of an aspect of the invention, and FIGS. 11 to 13 are diagrams schematically illustrating a spring and a support string as utilized in a scanner based on the second disclosed embodiment of an aspect of the invention.

In FIGS. 10 to 13, there are illustrated a scanner 200, a mirror 205, a mirror holder 210, a housing 220, a rotation shaft 226, a support part 222, a driving unit 230, a driving coil 232, a driving magnet 234, a sensing magnet 240, a Hall sensor 245, a spring 250, a hole 252, and a support string 260.

In this embodiment, a scanner 200 is presented, in which the other end of the spring 250 may be prevented from contacting the support part 222 of the housing 220, by a support string 260 that passes through the other end of the spring 250, to prevent noise that may occur during the operation of the scanner 200.

In describing this embodiment, the compositions for the mirror 205, mirror holder 210, housing 220, bearing, rotation shaft 226, driving unit 230, driving coil 232, driving magnet 234, sensing magnet 240, and Hall sensor 245 may be substantially the same as or may be in corresponding relationships with the components described for the first disclosed embodiment of an aspect of the invention, and thus will not be presented in further detail. The following description will focus more on the differences from the first disclosed embodiment described above, which include the support part 222, spring 250, and support string 260.

The support string 260 can have both ends coupled to the support part 222, and can pass through a hole 252, to be coupled with the other end of the spring 250 in a manner that allows sliding. In the first disclosed embodiment of the invention described above, the support part 222 may be the portions that would come into contact with the other end of the spring 250 if there is no soundproofing member used. However, the support part 222 can also encompass other portions, such as portions on the upper and lower casing of the housing 220, to which the rotation shaft may be rotatably coupled. In this embodiment, either end of the support string 260 may be coupled to the upper and lower casing of the housing 220, respectively, to prevent or reduce noise.

That is, a hole 252 may be formed in the other end of the spring 250, and the support string 260 may pass through this hole 252, to provide an arrangement in which the support string 260 is slidably coupled to the other end of the spring 250. Thus, when the mirror holder 210 is undergoing rotation (G), the support string 260 may not hinder the rotation of the mirror holder 210, as illustrated in FIG. 12. However, as the support string 260 slides through the other end of the spring 250 according to the rotation of the mirror holder 210, the support string 260 may prevent the spring 250 from moving at positions near the points where the rotation of the mirror holder 210 changes direction (F, H), as in the examples shown in FIG. 11 and FIG. 13, so that the other end of the spring 250 can be prevented from touching the support part 222.

Also, similar to the first disclosed embodiment, the length of the support string 260 may be adjusted, to balance the level of power consumption with the controllability during the direction changes in the rotation of the mirror holder 210. The descriptions on this matter will not be repeated.

While this embodiment has been described with a support string 260 as an example of the soundproofing member, it is to be appreciated that the invention encompasses other compositions and coupling relationships known to those skilled in the art that are capable of preventing or reducing noise caused by contact between the other end of the spring 250 and the support part 222.

Next, a description will be provided for a third disclosed embodiment, in which dampers interposed between the other end of the spring and the support part of the housing may be used as soundproofing members.

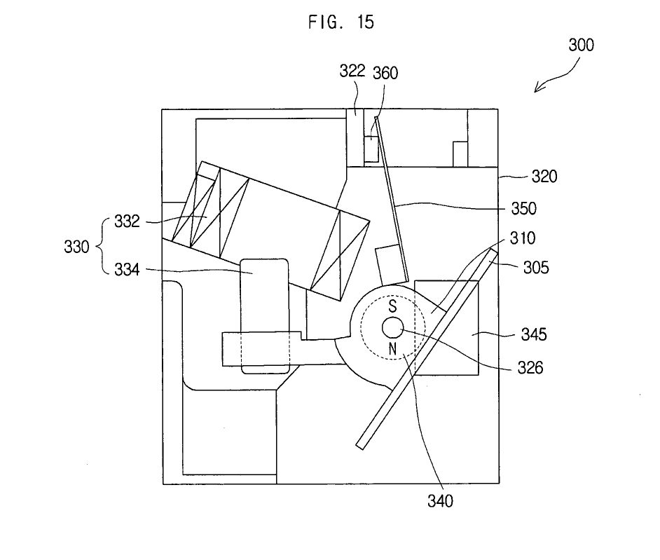

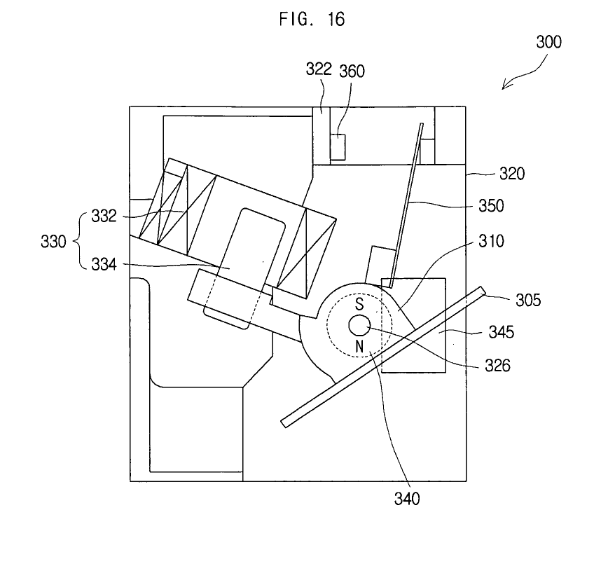

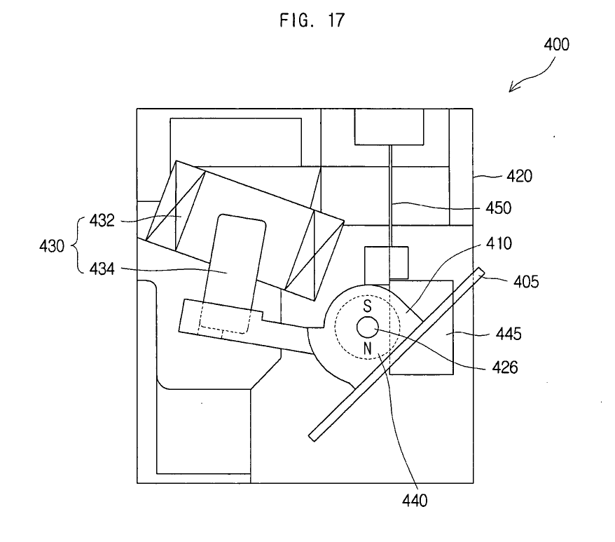

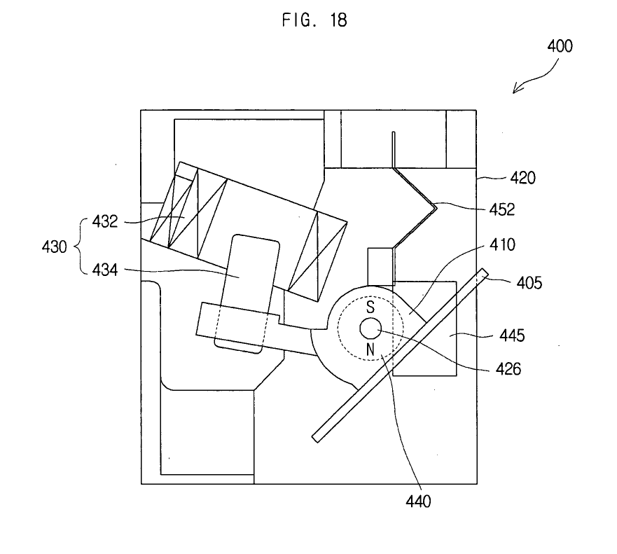

FIG. 14 is a cross-sectional view illustrating a scanner based on a third disclosed embodiment of an aspect of the invention, and FIGS. 15 and 16 are cross-sectional views illustrating the operation of a scanner based on the third disclosed embodiment of an aspect of the invention.

In FIGS. 14 to 16, there are illustrated a scanner 300, a mirror 305, a mirror holder 310, a housing 320, a rotation shaft 326, a support part 322, a driving unit 330, a driving coil 332, a driving magnet 334, a sensing magnet 340, a Hall sensor 345, a spring 350, and dampers 360.

In this embodiment, a scanner 300 is presented, in which the other end of the spring 350 may be prevented from contacting the support part 322 of the housing 320, by dampers 360 placed between the other end of the spring 350 and the support part 322 of the housing 320, to prevent noise that may occur during the operation of the scanner 300.

In describing this embodiment, the compositions for the mirror 305, mirror holder 310, housing 320, bearing, rotation shaft 326, driving unit 330, driving coil 332, driving magnet 334, sensing magnet 340, Hall sensor 345, and spring 350 may be substantially the same as or may be in corresponding relationships with the components described for the first disclosed embodiment of an aspect of the invention, and thus will not be presented in further detail. The following description will focus more on the differences from the first disclosed embodiment described above, particularly the dampers 360.

The dampers 360 may be interposed between the other end of the spring 350 and the support part 322. The dampers 360 can be made of a material that is capable of absorbing the impact of the spring 350 without causing noise when the other end of the spring 350 is made to contact the support part 322 according to the rotation of the mirror holder 310. Examples of such material may include sponges and paper, etc.

In the arrangement using dampers 360, the dampers 360 may not hinder the rotation of the mirror holder 310 while the mirror holder 310 is being rotated, as illustrated in FIG. 14. However, near the points where the direction of rotation of the mirror holder 310 is changed, the dampers 360 may prevent the other end of the spring 350 from contacting the support part 322 of the housing 320, as illustrated in FIGS. 15 and 16, so that the occurrence of noise may be avoided.

Also, similar to the first disclosed embodiment, the material and shape, etc., of the dampers 360 may be adjusted, to balance the level of power consumption with the controllability of the mirror holder 310 during the changes in direction of the rotation of the mirror holder 310. The descriptions on this matter will not be repeated.

While this embodiment has been described with dampers 360 as an example of the soundproofing member, it is to be appreciated that the invention encompasses other compositions and coupling relationships known to those skilled in the art that are capable of preventing or reducing noise caused by contact between the other end of the spring 350 and the support part 322.

Next, a description will be provided for a fourth disclosed embodiment, in which an elastic member is used as the supplementing unit that may have both ends secured.

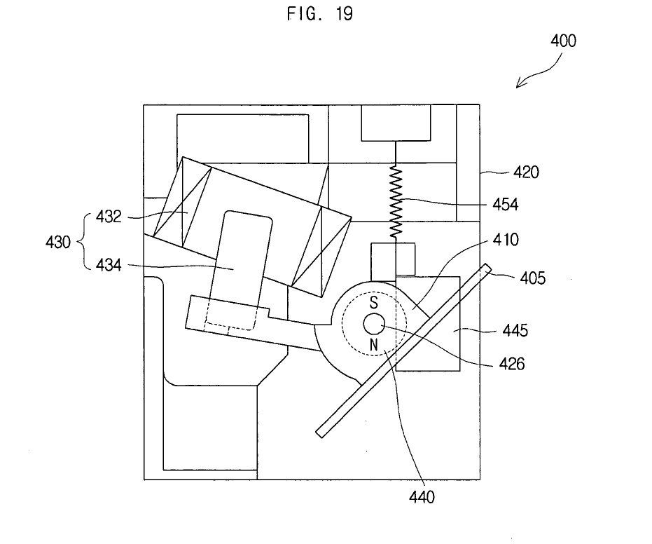

FIGS. 17 to 19 are cross-sectional views illustrating a scanner based on a fourth disclosed embodiment of an aspect of the invention. In FIGS. 17 to 19, there are illustrated a scanner 400, a mirror 405, a mirror holder 410, a housing 420, a rotation shaft 426, a support part, a driving unit 430, a driving coil 432, a driving magnet 434, a sensing magnet 440, a Hall sensor 445, an elastic member 450, a coil spring 454, and a flat spring 452.

In this embodiment, a scanner 400 is presented, in which an elastic member 450 is used that may have either end secured respectively to the housing 420 and the mirror holder 410, to prevent noise that may occur during the operation of the scanner 400.

In describing this embodiment, the compositions for the mirror 405, mirror holder 410, housing 420, bearing, rotation shaft 426, driving unit 430, driving coil 432, driving magnet 434, sensing magnet 440, and Hall sensor 445 may be substantially the same as or may be in corresponding relationships with the components described for the first disclosed embodiment of an aspect of the invention, and thus will not be presented in further detail. The following description will focus more on the differences from the first disclosed embodiment described above, which include the elastic member 450, flat spring 452, and coil spring 454.

The elastic member 450 may have either end coupled to the housing 420 and the mirror holder 410 respectively, as illustrated in FIG. 17, to provide an elastic force to the mirror holder 410. As both ends are secured, the noise that may otherwise be caused by the spring according to the rotation of the mirror holder 410 can be prevented.

In this embodiment, a folded flat spring 452 can be used as the elastic member 450, as illustrated in FIG. 18, and alternatively, a coil spring 454 can be used as the elastic member 450, as illustrated in FIG. 19. Furthermore, it is to be appreciated that the invention encompasses other compositions and coupling relationships known to those skilled in the art that are capable of supplementing the operation of the driving unit 430 and may have both ends secured to reduce or prevent noise.

Next, a description will be provided for a fifth disclosed embodiment, in which supplementing magnets are used as the supplementing unit.

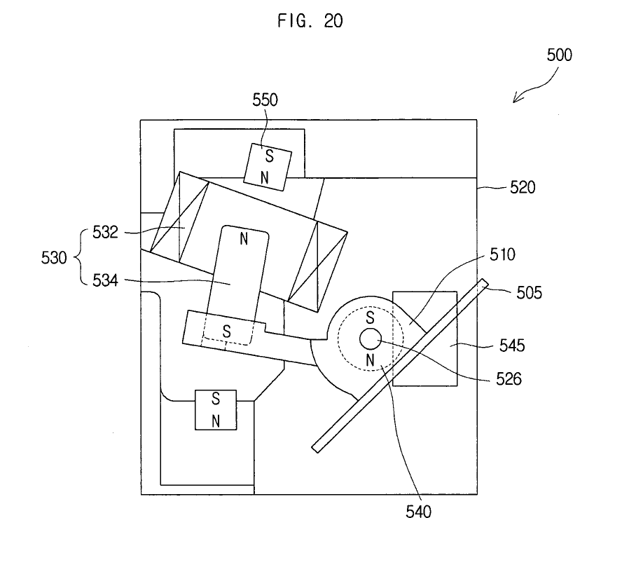

FIG. 20 is a cross-sectional view illustrating a scanner based on a fifth disclosed embodiment of an aspect of the invention. In FIG. 20, there are illustrated a scanner 500, a mirror 505, a mirror holder 510, a housing 520, a rotation shaft 526, a support part, a driving unit 530, a driving coil 532, a driving magnet 534, a sensing magnet 540, a Hall sensor 545, and supplementing magnets 550.

In this embodiment, a scanner 500 is presented, in which supplementing magnets 550 are used that may be arranged such that the driving magnet 534 is interposed in-between, to prevent noise that may occur during the operation of the scanner 500.

In describing this embodiment, the compositions for the mirror 505, mirror holder 510, housing 520, bearing, rotation shaft 526, driving unit 530, driving coil 532, driving magnet 534, sensing magnet 540, and Hall sensor 545 are substantially the same as or are in corresponding relationships with the components described for the first disclosed embodiment of an aspect of the invention, and thus will not be presented in further detail. The following description will focus more on the differences from the first disclosed embodiment described above, which include the supplementing magnets 550.

The supplementing magnets 550 can be arranged to have the driving magnet 534 interposed in-between, and can provide magnetic forces to the driving magnet 534. That is, the repulsion between the supplementing magnets 550 and the driving magnet 534 of the driving unit 530 can be used to supplement the rotational force of the driving unit 530 without noise near the points where the rotation of the mirror holder 510 changes direction.

The supplementing magnets 550 can be electromagnets, for example, where electricity may not be supplied when the mirror holder 510 is being rotated, and where electricity may be supplied to provide magnetism when the direction of rotation of the mirror holder 510 is being changed.

Accordingly, the supplementing magnets 550 may not hinder the rotation of the mirror holder 510 while the mirror holder 510 undergoes rotation. Near the positions where the rotation of the mirror holder 510 changes direction, however, the supplementing magnets 550 may prevent contact between the other end of the spring and the support part of the housing 520, to prevent or reduce noise.

Also, similar to the first disclosed embodiment, the duration of supplying electricity, etc., for the electromagnetic supplementing magnets 550 may be adjusted, to balance the level of power consumption with the controllability of the mirror holder 510 during the changes in direction of the rotation of the mirror holder 510. The descriptions on this matter will not be repeated.

While this embodiment has been described with supplementing magnets 550 as an example of the supplementing unit, it is to be appreciated that the invention encompasses other compositions and coupling relationships known to those skilled in the art that are capable of supplementing the operation of the driving unit 530 and reducing or preventing noise.

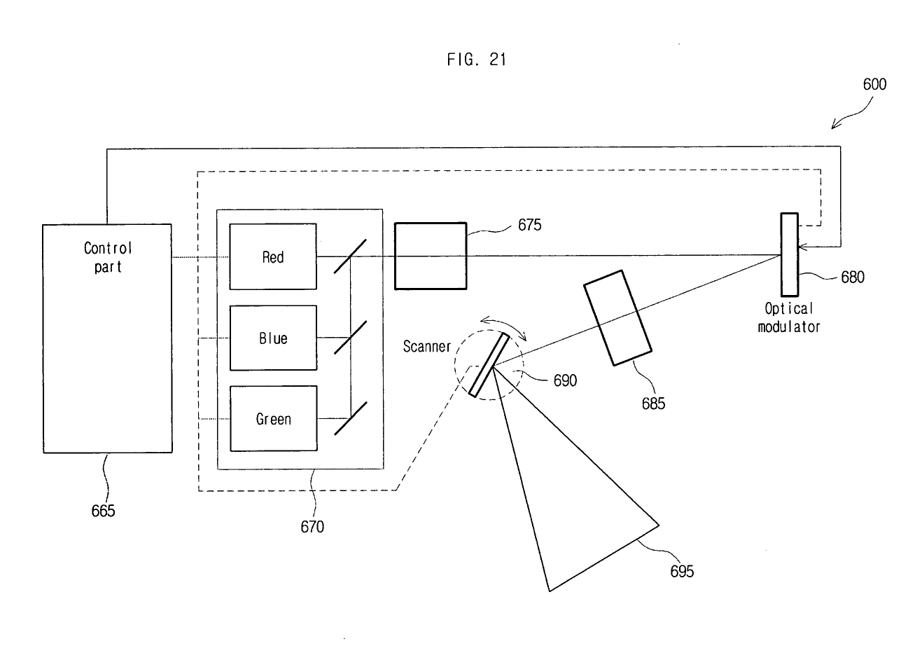

FIG. 21 is a cross-sectional view illustrating a display device based on an embodiment of another aspect of the invention. In FIG. 21, there are illustrated a display device 600, a light source 670, an illumination unit 675, an optical modulator 680, an imaging unit 685, a scanner 690, a screen 695, and a control part 665.

In this embodiment, a display device 600 is presented, in which a sensing magnet and a Hall sensor may be used to feedback control the operation of the scanner 690, and in which a supplementing unit may be used to supplement the driving force of the driving unit, so that an even image may be formed in a stable manner on the screen 695.

In describing this embodiment, the composition of the scanner 690 may be substantially the same as or may be in a corresponding relationship with the compositions described for the first to fifth disclosed embodiments of an aspect of the invention, and thus will not be presented in further detail. The following description will focus more on the differences from the first to fifth disclosed embodiments described above, which include the light source 670, illumination unit 675, optical modulator 680, imaging unit 685, screen 695, and control part 665.

In order to display an image, a light source 670 may emit light to an optical modulator 680. The light emitted by the light source 670 can be white light, or as illustrated in FIG. 21, the light source 670 may include color light sources that respectively emit one of the three primary colors of light, i.e. red, green, and blue light, to emit each of the color lights.

Examples of the light source 670 may include laser, LED's (light emitting diodes), and laser diodes. In cases where white light is emitted, a color separator may be included, to separate the white light into red, green, and blue light, under predefined conditions. The light source 670 may sequentially emit the red, green, and blue light in a predetermined order or in a certain other order.

An illumination unit 675 may be positioned between the light source 670 and the optical modulator 680 such that light projected from the light source 670 may pass the illumination unit 675 as it proceeds towards the optical modulator 680. As the light projected from the light source 670 passes the illumination unit 675, the light from light source 670 can be concentrated on the optical modulator 680.

The optical modulator 680 may modulate and project the light received from the light source 670. The optical modulator 680 can be made of multiple micro-mirrors arranged in a row, and can form a linear image corresponding to a vertical projection line or a horizontal projection line in one frame. That is, in response to a driving signal delivered from a control part 665, the optical modulator 680 may alter the displacement of each of the micro-mirrors corresponding to each pixel in the linear image, to alter the luminance and output modulated light.

For each of the multiple micro-mirrors included in the optical modulator 680, the displacement may be adjusted by the contraction and expansion of a piezoelectric element, to modulate the light received from the light source 670 and output modulated light. As such, the light can be modulated and outputted in correspondence to the displacements of the micro-mirrors.

The type of optical modulator 680 can be divided mainly into a direct type, which directly controls the on/off state of light, and an indirect type, which uses reflection and diffraction. The indirect type may be further divided into an electrostatic type and a piezoelectric type. These optical modulators 680 are applicable to embodiments of the invention regardless of the operation type.

An imaging unit 685 may be used in transferring the modulated light outputted from the optical modulator 680 to the scanner 690. The imaging unit 685 may include one or more lenses, by which the magnification can be adjusted as necessary, to transfer the modulated light after enlarging or compressing the image to fit the size of the optical modulator 680 and the size of the scanner 690. Afterwards, the light that has passed through the imaging unit 685 may be reflected by the scanner 690 in a particular angle to be scanned across the screen 695, whereby an image may be displayed.

A control part 665 may output a driving signal to the optical modulator 680, in order to obtain modulated light having the desired luminance values. That is, driving signals may be delivered to the piezoelectric elements of the optical modulator 680 to alter the displacements of the micro-mirrors, so that the optical modulator 680 may output modulated light having the desired luminance values. Here, a driving signal may include any one of a voltage signal, current signal, and digital data signal, etc.

As described with reference to the first disclosed embodiment set forth above, the control part 665 may receive sensing signals generated by the sensing magnet and Hall sensor positioned in the scanner 690, and output compensation signals as feedback. These compensation signals may be transferred to the driving unit and may be used in controlling the position or speed of the mirror holder, whereby the mirror of the scanner 690 may be controlled to undergo rotating oscillations in a more stable and uniform manner.

According to certain embodiments of the invention as set forth above, the periodical oscillating rotations of the mirror can be detected and used for feedback control, so that the mirror may reflect light with greater stability. Also, certain embodiments of the invention can be used to supplement the driving force of the driving unit, and can prevent noise that may occur during the rotation of the mirror.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention. As such, many embodiments other than those set forth above can be found in the appended claims.

What is claimed is:

1. A scanner comprising:
a mirror positioned on a light path and configured to reflect light;
a mirror holder supporting the mirror;
a housing rotatably supporting the mirror holder;
a driving unit configured to rotate the mirror holder such that the mirror rotates periodically in an oscillatory manner;
a sensing magnet coupled to a rotation center of the mirror holder and configured to rotate in correspondence to a rotation of the mirror holder; and
a Hall sensor coupled to the housing adjacent to the sensing magnet and configured to sense a rotation of the mirror holder.

2. The scanner of claim 1, wherein the sensing magnet is shaped as a circular plate and has a center axis positioned at a rotation center of the mirror holder.

3. The scanner of claim 1, wherein the driving unit comprises:
a driving coil coupled to the housing and having adjustable polarities; and
a driving magnet coupled to the mirror holder and inserted through the driving coil according to a change in polarity of the driving coil.

4. The scanner of claim 1, further comprising:
a supplementing unit configured to provide a rotational force supplementing a rotation of the mirror holder, when a rotational direction of the mirror holder is changed.

5. The scanner of claim 4, wherein the driving unit comprises:
a driving coil coupled to the housing and having adjustable polarities; and
a driving magnet coupled to the mirror holder and inserted through the driving coil according to a change in polarity of the driving coil,
and the supplementing unit comprises a plurality of supplementing magnets, the plurality of supplementing magnets arranged with the driving magnet interposed in-between and configured to provide magnetic forces to the driving magnet.

6. The scanner of claim 4, wherein the supplementing unit comprises an elastic member configured to provide an elastic force to the mirror holder.

7. The scanner of claim 6, wherein the housing comprises a support part formed thereon,
and the elastic member comprises a spring, the spring having one end coupled to the mirror holder and the other end supported by the support part so as to provide an elastic force according to a rotation of the mirror holder.

8. The scanner of claim 7, further comprising:
a soundproofing member coupled to the support part and configured to reduce noise caused by contact between the support part and the other end of the spring.

9. The scanner of claim 8, wherein the soundproofing member comprises a damper, the damper interposed between the support part and the other end of the spring.

10. The scanner of claim 8, wherein the soundproofing member comprises a support string, the support string coupled to the support part and the other end of the spring to prevent contact between the support part and the other end of the spring.

11. The scanner of claim 10, wherein the support string comprises a plurality of unit support strings, the plurality of unit support strings each having either end coupled to the support part and the other end of the spring.

12. The scanner of claim 10, wherein a hole is formed in the other end of the spring,
and the support string has both ends coupled to the support part and is coupled to the other end of the spring through the hole such that the spring is able to slide along the support string.

13. A display device comprising:
a light source;
an optical modulator configured to modulate and output light received from the light source; and
a scanner configured to scan the light received from the optical modulator onto a screen,
wherein the scanner comprises:
a mirror positioned on a light path and configured to reflect light;
a mirror holder supporting the mirror;
a housing rotatably supporting the mirror holder;
a driving unit configured to rotate the mirror holder such that the mirror rotates periodically in an oscillatory manner;
a sensing magnet coupled to a rotation center of the mirror holder and configured to rotate in correspondence to a rotation of the mirror holder; and
a Hall sensor coupled to the housing adjacent to the sensing magnet and configured to sense a rotation of the mirror holder.

14. The display device of claim 13, wherein the sensing magnet is shaped as a circular plate and has a center axis positioned at a rotation center of the mirror holder.

15. The display device of claim 13,.wherein the driving unit comprises:
a driving coil coupled to the housing and having adjustable polarities; and
a driving magnet coupled to the mirror holder and inserted through the driving coil according to a change in polarity of the driving coil.

16. The display device of claim 13, further comprising:
a supplementing unit configured to provide a rotational force supplementing a rotation of the mirror holder, when a rotational direction of the mirror holder is changed.

17. The display device of claim 16, wherein the driving unit comprises:
a driving coil coupled to the housing and having adjustable polarities; and
a driving magnet coupled to the mirror holder and inserted through the driving coil according to a change in polarity of the driving coil,
and the supplementing unit comprises a plurality of supplementing magnets, the plurality of supplementing magnets arranged with the driving magnet interposed in-between and configured to provide magnetic forces to the driving magnet.

18. The display device of claim 16, wherein the supplementing unit comprises an elastic member configured to provide an elastic force to the mirror holder.

19. The display device of claim 18, wherein the housing comprises a support part formed thereon,
and the elastic member comprises a spring, the spring having one end coupled to the mirror holder and the other end supported by the support part so as to provide an elastic force according to a rotation of the mirror holder.

20. The display device of claim 19, further comprising:
a soundproofing member coupled to the support part and configured to reduce noise caused by contact between the support part and the other end of the spring.

21. The display device of claim 20, wherein the soundproofing member comprises a damper, the damper interposed between the support part and the other end of the spring.

22. The display device of claim 20, wherein the soundproofing member comprises a support string, the support string coupled to the support part and the other end of the spring to prevent contact between the support part and the other end of the spring.

23. The display device of claim 22, wherein the support string comprises a plurality of unit support strings, the plurality of unit support strings each having either end coupled to the support part and the other end of the spring.

24. The display device of claim 22, wherein a hole is formed in the other end of the spring,
and the support string has both ends coupled to the support part and is coupled to the other end of the spring through the hole such that the spring is able to slide along the support string.
